(19) United States
(12) Patent Application Publication
(10) Pub. No.: US 2026/0247557 A1
(43) Pub. Date: Aug. 20, 2026

(54) REMOTE CONTROLLER AND TRANSMITTER-RECEIVER USING THE SAME

(71) Applicant: Bingxia Xie, Dongguan (CN)

(72) Inventor: Bingxia Xie, Dongguan (CN)

(21) Appl. No.: 19/642,997

(22) Filed: Apr. 9, 2026

(30) Foreign Application Priority Data
Mar. 24, 2026 (CN) 202620367511.5

(51) Int. Cl. H05K 5/06; G06F 3/0338; G06F 3/038; H04N 23/52; H04N 23/661; H05K 5/00

(52) U.S. Cl. CPC H05K 5/069; G06F 3/0338; G06F 3/038; H04N 23/52; H04N 23/661; H05K 5/0086

(57) ABSTRACT

This application provides an underwater remote controller, which includes a housing, at least one sealing element, at least one button, a detection unit, a battery, and a circuit board; the housing includes an upper housing and a lower housing; the upper housing and the lower housing are fixedly connected; the upper housing or the lower housing is provided with at least one through hole; the at least one sealing element is made of an elastic material with waterproof performance; the sealing element is disposed at the position of the through hole, and configured such that the sealing element, the upper housing, and the lower housing are fixedly connected to jointly define a sealed accommodating space.

### CROSS-REFERENCE TO RELATED APPLICATIONS

This application claims priority to Chinese Patent Application No. 202620367511.5, filed on March 24, 2026, which is hereby incorporated by reference in its entirety.

### TECHNICAL FIELD

This application relates to the technical field of remote control devices, and more particularly relates to a remote controller and a transmitter-receiver using the remote controller.

### BACKGROUND

In daily life, a mobile phone, as a common mobile electronic device, already has many additional functions beyond communication functions, such as image capturing. With people’s pursuit of a novel life, the niche hobby of underwater photography is increasingly favored by the public.

According to the inventors’ understanding, in the current technology, in order to use a mobile phone for underwater image capture, a common method is to place a waterproof phone case on the mobile phone; the waterproof phone case is provided with a specific button; the button corresponds to a shortcut image capture key of the mobile phone, and people only need to press the button to trigger the shortcut image capture key, thereby achieving image capture.

However, with continuous updates and iterations of mobile phone models, in order to adapt to different mobile phones, people need to purchase different waterproof phone cases to achieve underwater image capture, which invisibly increases the usage cost.

### SUMMARY

Based on the above technical problem, this application provides an underwater remote controller, comprising a housing, at least one sealing element, at least one button, a detection unit, a battery, and a circuit board; the housing comprises an upper housing and a lower housing, the upper housing and the lower housing are fixedly connected; the upper housing or the lower housing is provided with at least one through hole; the at least one sealing element is made of an elastic material with waterproof performance; the sealing element is disposed at the position of the through hole, configured such that the sealing element, the upper housing, and the lower housing are fixedly connected to jointly define a sealed accommodating space; the at least one button is disposed corresponding to the sealing element, configured such that the button is rotated through the sealing element; the detection unit is configured to detect rotation parameters of the button; the button, the detection unit, the battery, and the circuit board are electrically connected; the button, the detection unit, the battery, and the circuit board are all installed in the accommodating space.

This application further provides a transmitter-receiver, which comprises an underwater remote controller and a receiver; the underwater remote controller comprises a housing, at least one sealing element, at least one button, a detection unit, a battery, and a circuit board; the housing comprises an upper housing and a lower housing; the upper housing and the lower housing are fixedly connected; the upper housing or the lower housing is provided with at least one through hole; the at least one sealing element is made of an elastic material with waterproof performance; the sealing element is disposed at the position of the through hole, configured such that the sealing element, the upper housing, and the lower housing are fixedly connected to jointly define a sealed accommodating space; the at least one button is disposed corresponding to the sealing element, configured such that the button is rotated through the sealing element; the detection unit is configured to detect rotation parameters of the button; the button, the detection unit, the battery, and the circuit board are electrically connected; the button, the detection unit, the battery, and the circuit board are all installed in the accommodating space. The receiver comprises a receiving unit and a display unit; the receiving unit and the display unit are electrically connected. The receiving unit is configured to receive the remote control signal; the display unit is configured to display cursor information according to the remote control signal received by the receiving unit; the receiving unit and the display unit are electrically connected.

This application further provides a transmitter-receiver, which comprises an underwater remote controller and a smart terminal device; the underwater remote controller comprises a housing, at least one sealing element, at least one button, a detection unit, a battery, and a circuit board; the housing comprises an upper housing and a lower housing; the upper housing and the lower housing are fixedly connected; the upper housing or the lower housing is provided with at least one through hole; the at least one sealing element is made of an elastic material with waterproof performance; the sealing element is disposed at the position of the through hole, configured such that the sealing element, the upper housing, and the lower housing are fixedly connected to jointly define a sealed accommodating space; the at least one button is disposed corresponding to the sealing element, configured such that the button is rotated through the sealing element; the detection unit is configured to detect rotation parameters of the button; the button, the detection unit, the battery, and the circuit board are electrically connected; the button, the detection unit, the battery, and the circuit board are all installed in the accommodating space. The receiver comprises a receiving unit and a display unit; the receiving unit and the display unit are electrically connected. The smart terminal device is electrically connected with the underwater remote controller; the smart terminal device comprises a receiving unit, a processing unit, and a display unit. The receiving unit is configured to receive the remote control signal; the processing unit is configured to parse the remote control signal and generate cursor information; the display unit is configured to receive the cursor information and display the cursor information; the receiving unit, the processing unit, and the display unit are electrically connected.

### BRIEF DESCRIPTION OF THE DRAWINGS

The drawings described herein are used to provide a further understanding of this application and constitute a part of this application; the schematic embodiments of this application and their descriptions are used to explain this application and do not constitute an improper limitation of this application. In the following, some specific embodiments of this application will be described in detail with reference to the drawings in an exemplary rather than limiting manner. The same or similar reference numerals in the drawings denote the same or similar components or parts, and those of ordinary skill in the art should understand that these drawings are not necessarily drawn to scale, wherein:

FIG. 1 is a schematic diagram of the overall structure of an underwater remote controller provided by this application from a first perspective;

FIG. 2 is a schematic diagram of the overall structure of the underwater remote controller provided by this application from a second perspective;

FIG. 3 is an overall block diagram of the underwater remote controller provided by this application;

FIG. 4 is an exploded structural schematic diagram of the underwater remote controller provided by this application;

FIG. 5 is a schematic diagram of a cross-sectional structure of the underwater remote controller provided by this application along plane A-A;

FIG. 6 is a schematic diagram of the structure of an annular button shown in FIG. 4 from a first perspective;

FIG. 7 is a schematic diagram of the structure of the annular button shown in FIG. 4 from a second perspective;

FIG. 8 is a schematic diagram of the structure of a sealing element shown in FIG. 4 from a first perspective;

FIG. 9 is a schematic diagram of the structure of the sealing element shown in FIG. 4 from a second perspective;

FIG. 10 is a schematic diagram of the structure of a transmitter-receiver provided by this application;

FIG. 11 is a schematic diagram of the structure of another transmitter-receiver provided by this application;

FIG. 12 is a schematic diagram of the structure of a smart terminal device shown in FIG. 11;

FIG. 13 is a schematic diagram of the overall structure of another underwater remote controller provided by this application.

### DETAILED DESCRIPTION OF EMBODIMENTS

In the following, in conjunction with the drawings in the embodiments of this application, the technical solutions in the embodiments of this application will be clearly and completely described; of course, the described embodiments are only a part of the embodiments of this application, rather than all of the embodiments. Based on the embodiments in this application, all other embodiments obtained by those of ordinary skill in the art without creative work fall within the protection scope of this application.

It should be noted that all directional indications (such as up, down, left, right, front, rear, etc.) in the embodiments of this application are only used to explain the relative positional relationship, movement conditions, etc. between components under a certain specific posture (as shown in the drawings), and if the specific posture changes, the directional indications also change accordingly.

In addition, descriptions such as “first” and “second” in this application are only used for descriptive purposes and cannot be understood as indicating or implying relative importance or implicitly indicating the quantity of the indicated technical features. Thus, features defined as “first” or “second” may explicitly or implicitly include at least one such feature. In the description of this application, “a plurality of” means at least two, such as two, three, etc., unless otherwise explicitly and specifically defined.

In this application, unless otherwise expressly specified and limited, the terms “connected,” “fixed,” etc. shall be understood in a broad sense; for example, “fixed” can be a fixed connection, a detachable connection, or formed integrally; it can be a mechanical connection or an electrical connection; it can be a direct connection or an indirect connection through an intermediate medium; it can be internal communication between two elements or an interaction relationship between two elements, unless otherwise expressly limited. For a person of ordinary skill in the art, the specific meanings of the aforementioned terms in this application can be understood according to specific circumstances.

The drawings appearing in this application are only for illustrative explanation; the dimensions and shapes involved therein are only one form of embodiment and shall not be construed as limiting the scope of protection of the claims.

In addition, the technical solutions among the various embodiments of this application can be combined with each other, but such combination must be based on the ability of a person of ordinary skill in the art to implement; when the combination of technical solutions results in mutual contradiction or cannot be implemented, such combination shall be deemed not to exist and shall not fall within the scope of protection claimed in this application.

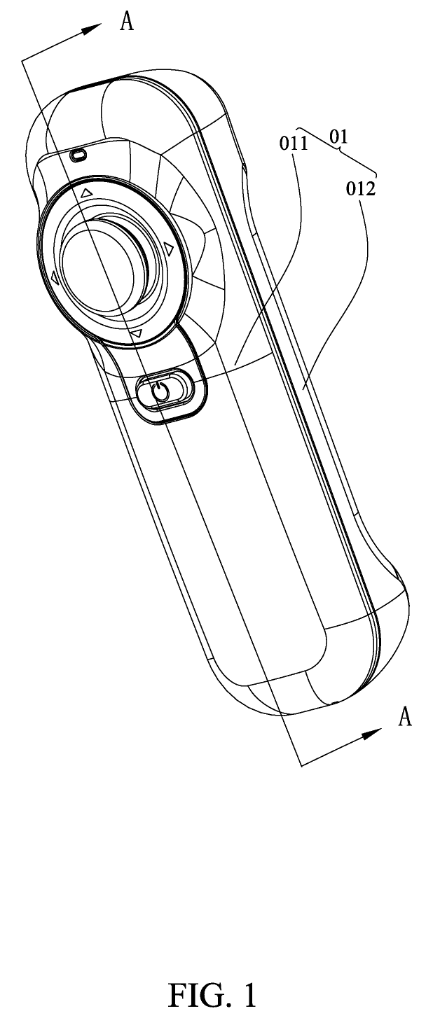

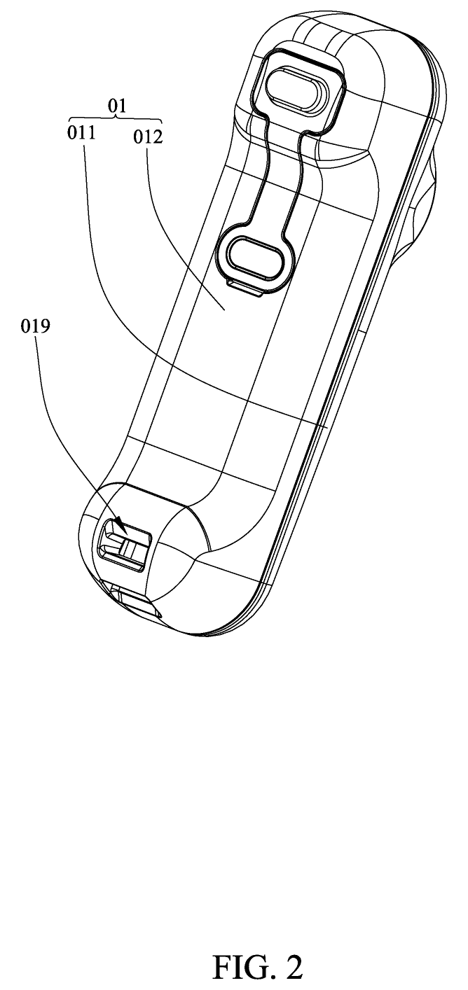

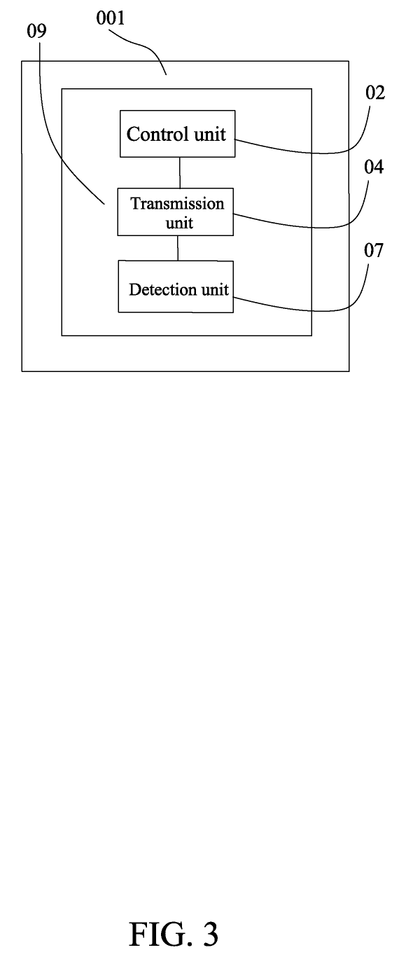

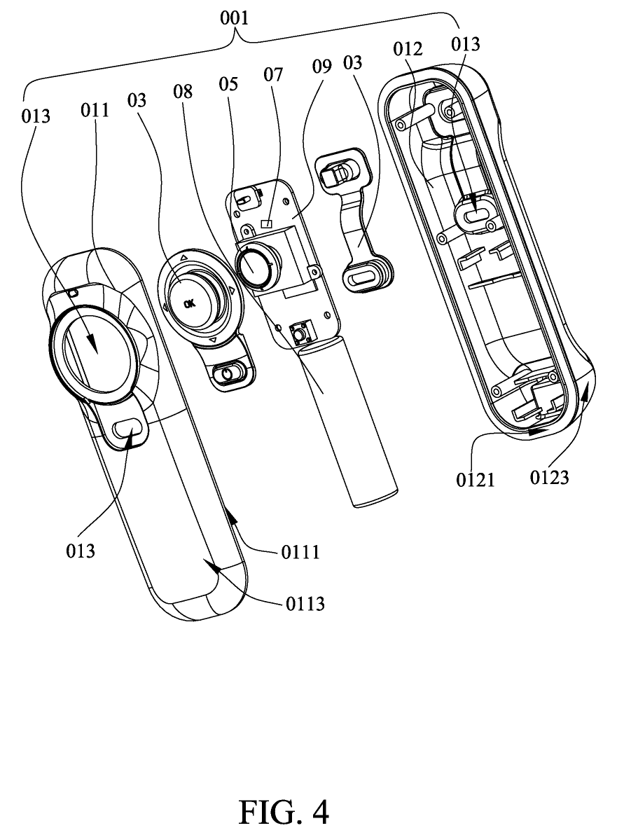

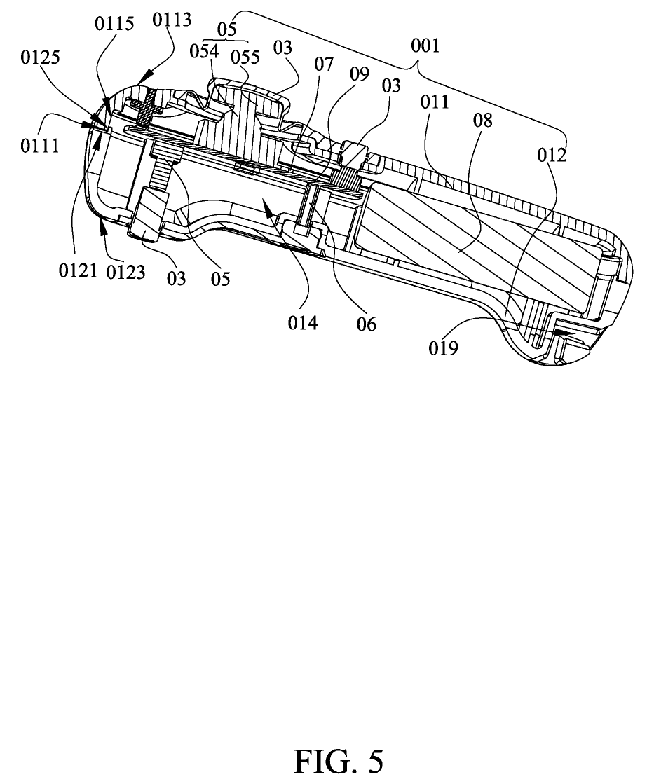

Please refer to FIG. 1 to FIG. 4; FIG. 1 is a schematic diagram of the overall structure of an underwater remote controller provided by this application from a first perspective; FIG. 2 is a schematic diagram of the overall structure of the underwater remote controller provided by this application from a second perspective; FIG. 3 is an overall block diagram of the underwater remote controller provided by this application; FIG. 4 is an exploded structural schematic diagram of the underwater remote controller provided by this application; FIG. 5 is a schematic diagram of a cross-sectional structure of the underwater remote controller provided by this application along plane A-A. The underwater remote controller 001 provided by this application includes a housing 01, at least one sealing element 03, at least one button 05, a detection unit 07, a battery 08, and a circuit board 09; the housing 01 includes an upper housing 011 and a lower housing 012; the upper housing 011 and the lower housing 012 are fixedly connected; the upper housing 011 or the lower housing 012 is provided with at least one through hole 013; the at least one sealing element 03 is an elastic material with waterproof performance; the sealing element 03 is disposed at the position of the through hole 013 and configured such that the sealing element 03, the upper housing 011, and the lower housing 012 are fixedly connected to jointly define a sealed accommodating space 014; the at least one button 05 is disposed corresponding to the sealing element 03 and configured such that the button 05 is rotated through the sealing element 03; the detection unit 07 is configured to detect rotation parameters of the button 05; the button 05, the detection unit 07, the battery 08, and the circuit board 09 are electrically connected; the button 05, the detection unit 07, the battery 08, and the circuit board 09 are all installed in the accommodating space 014.

It should be noted that the rotation parameters may include, but are not limited to, rotation angle, rotation speed, rotation displacement, and rotation direction.

It should be noted that the overall shape of the housing 01 defined by the upper housing 011 and the lower housing 012 is a slender rectangular parallelepiped, and a chamfer is provided at each corner to make the housing 01 easier to hold. Wherein, both the upper housing 011 and the lower housing 012 are thin shell structures with openings, and their openings are correspondingly disposed and can cooperate with each other to ultimately define one accommodating space 014. The materials of the upper housing 011 and the lower housing 012 are specifically limited here, and may be metal, plastic, silicone, and various other materials, and in general embodiments plastic materials are commonly used. In addition, the fixed connection manner between the upper housing 011 and the lower housing 012 may be at least one of integral forming, welding, snap-fit, interference fit, magnetic connection, screw or bolt connection, and adhesive bonding. In general embodiments, in order to pursue connection stability and waterproof performance, the fixed connection manner may simultaneously include screw connection and adhesive bonding.

It should be noted that the thicknesses of the upper housing 011 and the lower housing 012 are substantially the same.

As shown in FIG. 4, the shape of the through hole 013 provided in the upper housing 011 and the lower housing 012 is not specifically limited, and may be circular, quadrilateral, pentagonal, hexagonal, heptagonal, or various irregular shapes; when the through hole 013 is provided in the upper housing 011, it penetrates through the upper housing 011; when the through hole 013 is provided in the lower housing 012, it penetrates through the lower housing 012. The quantity of the through hole 013 is generally at least two.

Continuing to refer to FIG. 4, it can be seen from FIG. 4 that the sealing element 03 is disposed at the position of the through hole 013, which is equivalent to the sealing element 03 covering the position of the through hole 013; at least a portion of the sealing element 03 is fixedly connected with the housing 01 to jointly define the accommodating space 014, ensuring the sealing performance of the accommodating space 014. The material of the sealing element 03 is an elastic material, and the elastic material may be silicone, synthetic rubber, plastic, rubber, or other flexible polymer materials. In this application, the fixed connection manner may be at least one of integral forming, welding, snap-fit, interference fit, magnetic connection, screw or bolt connection, and adhesive bonding.

Wherein, the type of the button 05 may include at least one of a power button, an image capture button, an annular button, and a displacement button.

Wherein, the detection unit 07 may be at least one of a gyroscope, a position sensor, and an angular displacement sensor, and in this application an angular displacement sensor may be selected; the angular displacement sensor is an electronic component used to detect rotation parameters or angular displacement of an object. It can convert a mechanical rotation angle change into an electrical signal for a control system to read and process. The angular displacement sensor is installed on the circuit board 09 and has an electrical connection relationship with the circuit board 09.

Please mainly refer to FIG. 3; the underwater remote controller 001 further includes a control unit 02 and a transmission unit 04, and is configured to receive the rotation parameters of the button 05 detected by the detection unit 07, parse the rotation parameters, and then generate a remote control signal; the transmission unit 04 is configured to transmit the remote control signal.

In some embodiments, the control unit 02 may include, but is not limited to, any one or a combination of: a microcontroller unit (MCU), a central processing unit (CPU), a digital signal processor (DSP), a field programmable gate array (FPGA), an application specific integrated circuit (ASIC), or a programmable logic controller (PLC).

In a preferred embodiment, the transmission unit may include, but is not limited to, an infrared transmission circuit, a radio frequency transmission chip, a Bluetooth chip, a Wi-Fi communication module, or a wired drive interface.

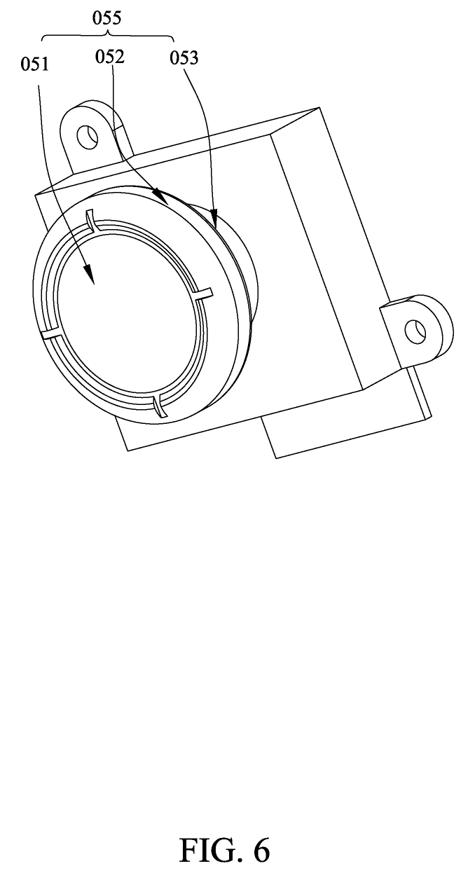

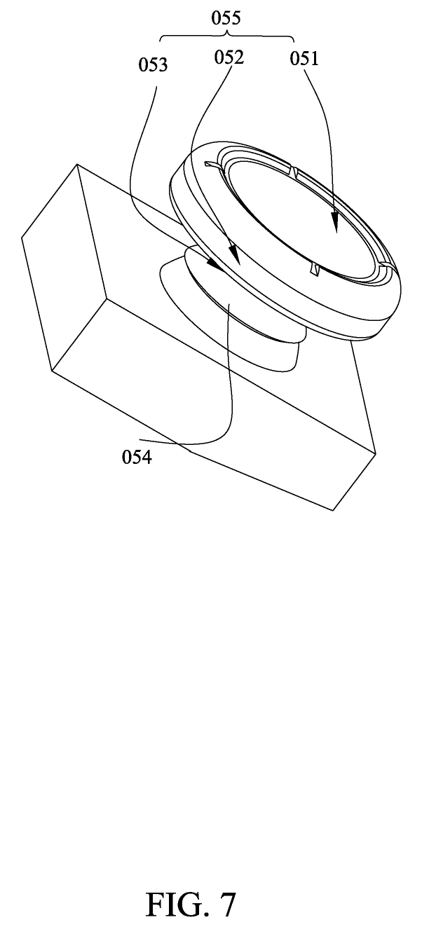

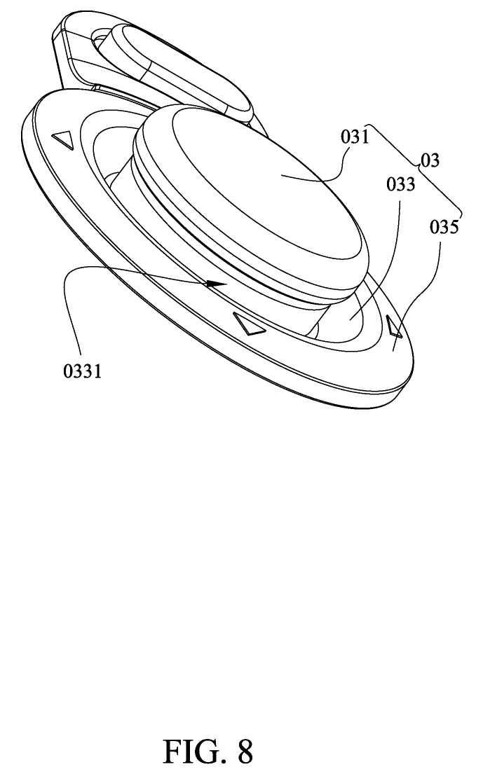

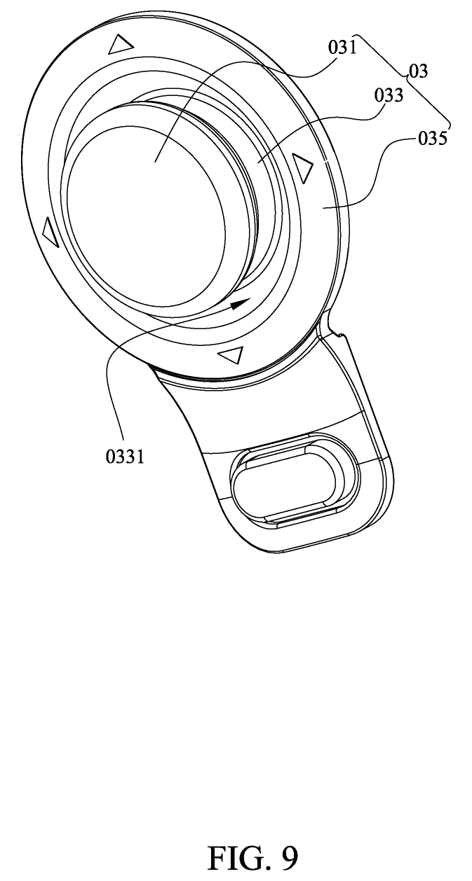

Please refer to FIG. 6, FIG. 7, FIG. 8, and FIG. 9; wherein, FIG. 6 is a schematic diagram of the structure of the annular button shown in FIG. 4 from a first perspective; FIG. 7 is a schematic diagram of the structure of the annular button shown in FIG. 4 from a second perspective; FIG. 8 is a schematic diagram of the structure of the sealing element shown in FIG. 4 from a first perspective; FIG. 9 is a schematic diagram of the structure of the sealing element shown in FIG. 4 from a second perspective.

The annular button 05 includes a top wall 051, a side wall 052, and a bottom wall 053; the top wall 051, the side wall 052, and the bottom wall 053 form a cylindrical operation platform 055, wherein the bottom wall 053 and the side wall 052 are both below the top wall 051; the detection unit 07 detects the rotation parameters of the annular button 05 by detecting the spatial position of the side wall 052 or the bottom wall 053. The annular button 05 further includes a support post 054, which is disposed below the bottom wall 053, between the bottom wall 053 and the circuit board 09, and the cylindrical operation platform 055 rotates about the support post 054.

In some embodiments, the support post 054 is at the center below the cylindrical operation platform 055. In this application, the connection relationship between the support post 054 and the cylindrical operation platform 055 may be integral forming or fixed connection. The fixed connection manner is the same as described above and will not be repeated. In order to facilitate operation of the button 05, the position of the sealing element 03 corresponds to the position of the cylindrical operation platform 055, and the shape of the sealing element 03 matches the shape of the cylindrical operation platform 055.

During operation, an operator presses the cylindrical operation platform 055 with a finger to rotate about the support post 054; at this time, the rotation parameters of the side wall 052 or the bottom wall 053 relative to the detection unit 07 will change; for example, the rotation parameters may include, but are not limited to, rotation angle, rotation speed, rotation displacement, and rotation direction. In some embodiments, the detection unit 07 may detect the rotation angle of the side wall 052 relative to the detection unit 07, or the detection unit 07 may detect the rotation angle of the bottom wall 053 relative to the detection unit 07, thereby calculating the rotation parameters of the button 05.

Please continue to refer to FIG. 8 and FIG. 9; the sealing element 03 includes an annular protrusion 031, a transition portion 033, and an edge portion 035, the edge portion 035 is disposed around the annular protrusion 031; the annular protrusion 031, the transition portion 033, and the edge portion 035 are sequentially disposed along a circumferential direction.

The annular protrusion 031 corresponds to the position of the cylindrical operation platform 055; the edge portion 035 is fixedly connected with the housing 01; a recessed region 0331 is formed in the area where the transition portion 033 is located; when the button 05 rotates, the volume of the recessed region 0331 changes. The button further includes at least one of a power button, an image capture button, and a displacement button.

When an operator presses the cylindrical operation platform 055 with a finger to rotate about the support post 054, the position of the cylindrical operation platform 055 relative to the housing 01 changes; the presence of the recessed region 0331 provides a buffer space for relative displacement between the cylindrical operation platform 055 and the housing 01, allowing the cylindrical operation platform 055 to complete rotation within a larger space, facilitating operation.

Please refer to FIG. 1 to FIG. 5; the underwater remote controller 001 further includes a charging port 06, which corresponds to the position of the through hole 013; the charging port 06, the button 05, the detection unit 07, the battery 08, and the circuit board 09 are electrically connected. Wherein, the charging port 06 is configured to be externally connected to mains electricity and then output electric power to the battery 08.

In some embodiments, the sealing element 03 and the charging port 06 are detachably connected; when in a charging stage, the charging port 06 is separated from the sealing element 03; when in a use state, the sealing element 03 covers the charging port 06. In a preferred embodiment, the charging port 06 may include, but is not limited to, the following types: USB Type-C interface; Lightning interface; Micro USB interface; Mini USB interface; USB-A interface; wireless charging module.

Please refer to FIG. 1 and FIG. 2; the upper housing 011 or the lower housing 012 is provided with a slot 019; the slot 019 penetrates through the upper housing 011 or the lower housing 012. The slot 019 is configured for external connection of a rope such as a soft cord for hanging the underwater remote controller 001. An operator may pass the soft cord through the slot 019 and then tie the soft cord to the body (neck or limb).

Please refer to FIG. 1, FIG. 2, FIG. 3, and FIG. 5. The upper housing 011 includes a first end face 0111 and an upper peripheral side wall 0113; the lower housing 012 includes a second end face 0121 and a lower peripheral side wall 0123; wherein, the upper peripheral side wall 0113 and the lower peripheral side wall 0123 define the overall contour of the housing 01. The first end face 0111 corresponds to the position of the second end face 0121; the first end face 0111 and the second end face 0121 are fixedly connected. It should be noted that the first end face 0111 and the upper peripheral side wall 0113 are divisions of regions of the upper housing 011, and the second end face 0121 and the lower peripheral side wall 0123 are divisions of regions of the lower housing 012. In some embodiments, the connection relationship between the first end face 0111 and the upper peripheral side wall 0113 is a fixed connection, and the connection relationship between the second end face 0121 and the lower peripheral side wall 0123 is a fixed connection; the fixed connection manner is the same as listed above and will not be repeated, and in the embodiments of this application, integral forming is preferably selected. The upper peripheral side wall 0113 and the lower peripheral side wall 0123 define the overall contour of the underwater remote controller 01. The fixed connection manner between the first end face 0111 and the second end face 0121 is also the same as listed above and will not be repeated. In some embodiments of this application, it is preferable to consider adopting a snap-fit connection and adhesive bonding between the two for fixed connection.

Furthermore, in a specific embodiment of the fixed connection between the first end face 0111 and the second end face 0121, the first end face 0111 is provided with a first limiting end face 0115, and the second end face 0121 is provided with a second limiting end face 0125; the first limiting end face 0115 corresponds to the position of the second limiting end face 0125, and the two are aligned to complete snap-fitting; in addition, the two also increase the adhesive area.

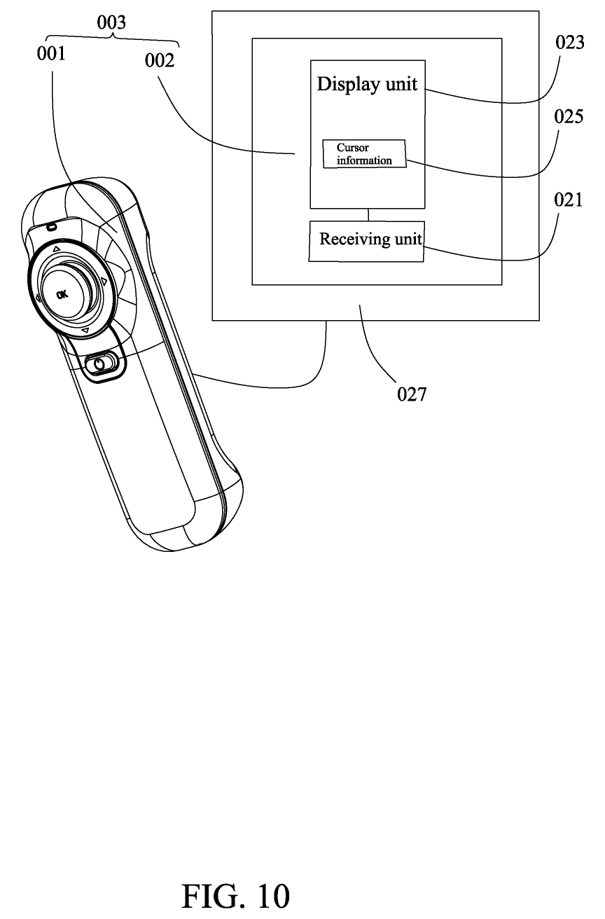

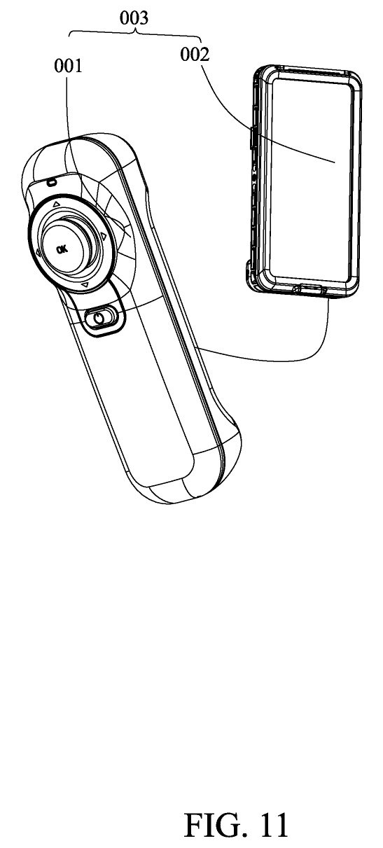

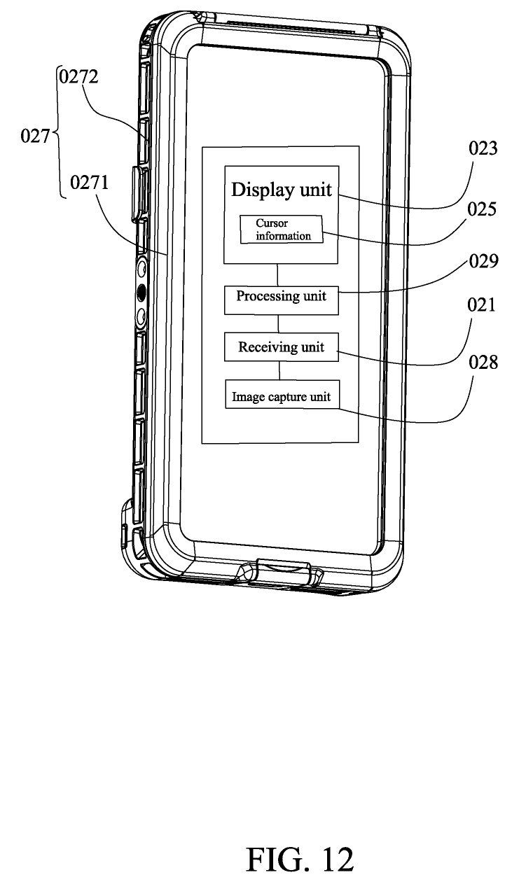

Please refer to FIG. 10, which is a schematic diagram of the structure of a transmitter-receiver provided by this application; FIG. 11 is a schematic diagram of the structure of another transmitter-receiver provided by this application; FIG. 12 is a schematic diagram of the structure of a smart terminal device shown in FIG. 11. As shown in FIG. 10, a transmitter-receiver 003 provided by this application includes an underwater remote controller 001 and a receiver 002; the specific structure of the underwater remote controller 001 refers to FIG. 1 to FIG. 5 and will not be repeated here. The receiver 002 includes a receiving unit 021 and a display unit 023; the receiving unit 021 is configured to receive a remote control signal; the display unit 023 is configured to display cursor information 025 according to the remote control signal received by the receiving unit 021; the receiving unit 021 and the display unit 023 are electrically connected. The receiver 002 and the underwater remote controller 001 are electrically connected.

It should be noted that, in preferred embodiments, the receiving unit 021 may include, but is not limited to, the following types: infrared receiving head, radio frequency receiving chip, radio frequency transceiver chip, Bluetooth chip, Wi-Fi chip, optical fiber receiving module, ultrasonic receiving sensor, or USB interface chip.

It should be noted that, in preferred embodiments, the display unit 023 may include, but is not limited to, a liquid crystal display (LCD), an organic light emitting diode display (OLED), an active matrix organic light emitting diode display (AMOLED), a micro light emitting diode display (Micro-LED), a light emitting diode dot matrix (LED Dot Matrix), a segment display (LED Segment Display), an electronic paper display (E-Paper / E-Ink), a thin film transistor liquid crystal display (TFT-LCD), a segment liquid crystal display (Segment LCD), a touch display, or any of the above display screens with integrated touch functionality.

In addition, it should be noted that during underwater operation of the receiver 002, a waterproof housing 027 is also required; the overall shape of the waterproof housing 027 is a rectangular parallelepiped; the receiving unit 021 and the display unit 023 are both installed in the waterproof housing 027, configured to place the receiving unit 021 and the display unit 023 in a sealed state.

Please refer to FIG. 11 and FIG. 12; a transmitter-receiver 003 provided by this application includes an underwater remote controller 001 and a smart terminal device 002; the specific structure of the underwater remote controller 001 refers to FIG. 1 to FIG. 5 and will not be repeated here. In the embodiments in FIG. 11 and FIG. 12, the specific embodiment of the receiver 002 at this time is a type of the smart terminal device 002; the smart terminal device 002 is electrically connected with the underwater remote controller 001; the smart terminal device 002 includes a receiving unit 021, a processing unit 029, and a display unit 023, and the three are electrically connected. The receiving unit 021 is configured to receive the remote control signal; the processing unit 029 is configured to parse the remote control signal and generate the cursor information 025; the display unit 023 is configured to receive the cursor information 025 and display the cursor information 025.

In some embodiments, the receiver 002 or the smart terminal device 002 may include, but is not limited to, the following types: smartphone, tablet computer, laptop computer, smartwatch, smart bracelet, smart glasses, smart earphones, smart camera, smart underwater thruster, or robot.

The specific implementation manners of the receiving unit 021 and the display unit 023 are the same as above and will not be repeated one by one. The processing unit 029 may include, but is not limited to, any one or a combination of a microcontroller unit (MCU), a central processing unit (CPU), a digital signal processor (DSP), a field programmable gate array (FPGA), an application specific integrated circuit (ASIC), or a programmable logic controller (PLC).

In some embodiments, the smart terminal device 002 further includes an image capture unit 028, which is configured to receive the cursor information 025 and complete an image capture operation. In some preferred embodiments, the image capture unit 028 may include, but is not limited to, the following types: complementary metal oxide semiconductor image sensor (CMOS Image Sensor), charge coupled device image sensor (CCD Image Sensor), infrared camera, thermal imaging camera, hyperspectral camera, panoramic camera, macro camera, wide-angle camera, telephoto camera, gimbal camera, or network camera (Webcam).

Similarly, it should be noted that during underwater operation of the receiver 002, a waterproof housing 027 is also required; the overall shape of the waterproof housing 027 is a rectangular parallelepiped; the receiving unit 021 and the display unit 023 are both installed in the waterproof housing 027, configured to place the receiving unit 021 and the display unit 023 in a sealed state. The waterproof housing 027 includes an upper cover 0271 and a lower cover 0272; the upper cover 0271 and the lower cover 0272 are detachably connected; the upper cover 0271 and the lower cover 0272 define a sealed space; the smart terminal device 002 is installed in the sealed space.

Please refer to FIG. 1 to FIG. 5, and FIG. 10 to FIG. 12. In actual use, the technical solution of this application does not require configuring different waterproof phone cases for different smart terminal devices 002 to achieve control, but instead achieves image capture operations of different models of smart terminal devices 002 by providing the underwater remote controller 001. In this process, the button 05 can achieve 360-degree rotation, facilitating control of the cursor information 025 to move on the display unit 023. For example, when the button 05 rotates to a certain position, the detection unit 07 detects the coordinate information, and then the transmission unit 04 sends the coordinate information to the smart terminal device 002; after the smart terminal device 002 receives the remote control signal, the processing unit 029 is configured to parse the remote control signal and generate cursor information 025 at that position, and then the display unit 023 displays the cursor information 025. Thus, operation of the smart terminal device 002 by the underwater remote controller 001 is achieved. When the cursor information 025 moves to a region corresponding to the image capture unit 028, the operator presses the button 05 to complete an image capture operation. Moreover, in actual operation, by providing the sealing element 03 and the waterproof housing 027, the smart terminal device 002 and the underwater remote controller 001 are also in a sealed state.

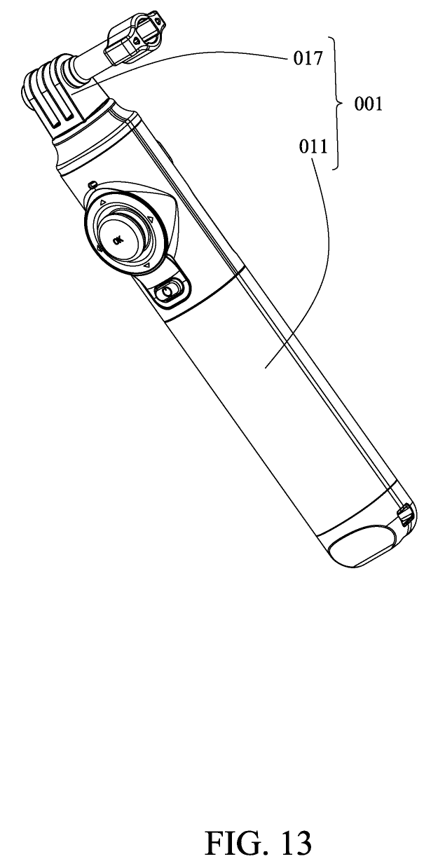

Please refer to FIG. 11 to FIG. 13; FIG. 13 is a schematic diagram of the overall structure of another underwater remote controller provided by this application. The underwater remote controller 001 further includes a plug connector 017, which is fixedly connected with the housing 011. The fixed connection manner is also the same as listed above and will not be repeated. In some embodiments of this application, it is preferable to consider adopting a snap-fit connection and adhesive bonding between the two for fixed connection.

The plug connector 017, as a connection structure, is configured to physically connect the underwater remote controller 001 and the smart terminal device 002. In some preferred embodiments, the physical connection may include, but is not limited to, the following types: welding connection, plug connection, screw connection (including screw, bolt, stud fixing), snap connection (including buckle, hook, slot matching), riveting connection, crimping connection, adhesive connection (including conductive adhesive bonding, insulating adhesive bonding), elastic contact connection (including spring sheet, pogo pin, spring contact), magnetic connection, interference fit connection, hinge connection, slide rail connection, cable tie fixing connection, sleeve connection (including pipe sleeve, shaft sleeve matching), threaded connection, keyway connection, or pin connection.

The electrical connection mentioned in this application may be a connection by wires in a physical sense, or may be an electrical signal connection using a wireless manner, and the electrical signal may be at least one of a current signal, a voltage signal, a resistance signal, a Bluetooth signal, or a Wi-Fi signal.

The descriptive terms “substantially”, “approximately”, “about”, and “generally” mentioned in this application mean that, relative to a standard value, the variation range may fluctuate within ±20%.

The meaning of “at least one” mentioned in this application is that it may be one case or a coexistence of multiple cases. For example, “at least one of A, B, and C” includes all combinations such as A alone, B alone, C alone, A and B coexisting, A and C coexisting, and so on. They will not be listed one by one.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A or B”, unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

The above descriptions are only embodiments of this application, and it should be pointed out that for those of ordinary skill in the art, improvements may be made without departing from the inventive concept of this application, and these all fall within the protection scope of this application.

What is claimed is:

1. An underwater remote controller, characterized by comprising:
a housing, the housing comprising:
an upper housing;
a lower housing; the upper housing and the lower housing are fixedly connected; the upper housing or the lower housing is provided with at least one through hole;
at least one sealing element, which is made of an elastic material with waterproof performance; the sealing element is disposed at the position of the through hole, configured such that the sealing element, the upper housing, and the lower housing are fixedly connected to jointly define a sealed accommodating space;
at least one button, which is disposed corresponding to the sealing element, and configured such that the button is rotated through the sealing element;
a detection unit, configured to detect rotation parameters of the button;
a battery;
a circuit board;
the button, the detection unit, the battery, and the circuit board are electrically connected; the button, the detection unit, the battery, and the circuit board are all installed in the accommodating space.

2. The underwater remote controller according to claim 1, characterized by further comprising:
a control unit, configured to receive the rotation parameters of the button detected by the detection unit, and to parse the rotation parameters, and then generate a remote control signal;
a transmission unit, configured to transmit the remote control signal.

3. The underwater remote controller according to claim 1, characterized in that, the button further comprises an annular button, which comprises:
a top wall;
a side wall;
a bottom wall; the top wall, the side wall, and the bottom wall form a cylindrical operation platform; wherein, the bottom wall and the side wall are both below the top wall.

4. The underwater remote controller according to claim 3, characterized in that, the annular button further comprises a support post, which is disposed below the bottom wall, between the bottom wall and the circuit board; the cylindrical operation platform rotates about the support post.

5. The underwater remote controller according to claim 4, characterized in that, the support post is at the center of the cylindrical operation platform.

6. The underwater remote controller according to claim 3, characterized in that, the position of the sealing element corresponds to the position of the cylindrical operation platform; the shape of the sealing element matches the shape of the cylindrical operation platform.

7. The underwater remote controller according to claim 6, characterized in that, the sealing element comprises:
an annular protrusion;
a transition portion;
an edge portion; the edge portion is disposed around the annular protrusion; the annular protrusion, the transition portion, and the edge portion are sequentially disposed along a circumferential direction;
the annular protrusion corresponds to the position of the cylindrical operation platform; the edge portion is fixedly connected with the housing; a recessed region is formed in the area of the transition portion;
when the button rotates, the volume of the recessed region changes.

8. The underwater remote controller according to claim 1, characterized in that, the button further comprises at least one of a power button, an image capture button, and a displacement button.

9. The underwater remote controller according to claim 1, characterized by further comprising:
a charging port, which corresponds to the position of the through hole; the charging port, the button, the detection unit, the battery, and the circuit board are electrically connected.

10. The underwater remote controller according to claim 8, characterized in that, the sealing element and the charging port are detachably connected;
when in a charging stage, the charging port and the sealing element are separated;
when in a use state, the sealing element covers the charging port.

11. The underwater remote controller according to claim 1, characterized in that, the upper housing or the lower housing is provided with a slot; the slot penetrates through the upper housing or the lower housing.

12. The underwater remote controller according to claim 1, characterized in that, the upper housing comprises a first end face and an upper peripheral side wall; the lower housing comprises a second end face and a lower peripheral side wall;
the first end face corresponds to the position of the second end face; the first end face and the second end face are fixedly connected;
the upper peripheral side wall and the lower peripheral side wall define the overall contour of the underwater remote controller.

13. The underwater remote controller according to claim 12, characterized in that, the first end face is provided with a first limiting end face, and the second end face is provided with a second limiting end face; the first limiting end face corresponds to the position of the second limiting end face.

14. The underwater remote controller according to claim 1, characterized by further comprising a plug connector, which is fixedly connected with the housing.

15. A transmitter-receiver, characterized by comprising:
an underwater remote controller, comprising:
a housing, the housing comprising:
an upper housing;
a lower housing; the upper housing and the lower housing are fixedly connected; the upper housing or the lower housing is provided with at least one through hole;
at least one sealing element, which is made of an elastic material with waterproof performance; the sealing element is disposed at the position of the through hole, configured such that the sealing element, the upper housing, and the lower housing are fixedly connected to jointly define a sealed accommodating space;
at least one button, which is disposed corresponding to the sealing element, and configured such that the button is rotated through the sealing element;
a detection unit, configured to detect rotation parameters of the button;
a battery;
a circuit board;
the button, the detection unit, the battery, and the circuit board are electrically connected; the button, the detection unit, the battery, and the circuit board are all installed in the accommodating space;
a control unit, configured to receive the rotation parameters of the button detected by the detection unit, and to parse the rotation parameters, and then generate a remote control signal;
a transmission unit, configured to transmit the remote control signal;
a receiver, comprising:
a receiving unit, configured to receive the remote control signal;
a display unit, configured to display cursor information according to the remote control signal received by the receiving unit; the receiving unit and the display unit are electrically connected.

16. The transmitter-receiver according to claim 15, characterized in that, the receiver and the underwater remote controller are electrically connected.

17. The transmitter-receiver according to claim 15, characterized in that, the receiver comprises a waterproof housing; the overall shape of the waterproof housing is a rectangular parallelepiped; the receiving unit and the display unit are both installed in the waterproof housing, configured to place the receiving unit and the display unit in a sealed state.

18. The transmitter-receiver according to claim 15, characterized in that, the receiver further comprises:
a processing unit, configured to parse the remote control signal and generate the cursor information.

19. The transmitter-receiver according to claim 18, characterized in that, the receiver further comprises:
an image capture unit, configured to receive the cursor information and complete an image capture operation.

20. The transmitter-receiver according to claim 19, characterized by further comprising a waterproof housing, which comprises:
an upper cover and a lower cover; the upper cover and the lower cover are detachably connected; the upper cover and the lower cover define a sealed space; and the receiver is installed in the sealed space.
